(19) United States
(12) Patent Application Publication
(10) Pub. No.: US 2026/0157198 A1
(43) Pub. Date: Jun. 4, 2026

(54) WIRING SUBSTRATE

(71) Applicant: IBIDEN CO., LTD., Gifu (JP)

(72) Inventors: Nobuhisa KURODA, Gifu (JP); Ayumu KUBOTA, Gifu (JP); Toshihide MAKINO, Gifu (JP)

(73) Assignee: IBIDEN CO., LTD., Gifu (JP)

(21) Appl. No.: 19/398,961

(22) Filed: Nov. 24, 2025

(30) Foreign Application Priority Data
Dec. 4, 2024 (JP) 2024-211520

(51) Int. Cl. H01L 23/498; H01L 23/15

(52) U.S. Cl. CPC H10W 70/635; H10W 70/692

(57) ABSTRACT

A wiring substrate includes a core part including a glass plate, a first build-up part including conductor layers and insulating layers, and a second build-up part including conductor layers and insulating layers. Each of the first and second build-up parts is formed such that the conductor layers include four conductor layers and the insulating layers include four insulating layers, the core part includes through-hole conductors formed in the glass plate such that the through-hole conductors connect the conductor layers in the first build-up part on the first surface and the second build-up part on the second surface of the glass plate, and the glass plate has a thickness in the range of 0.7 mm to 1.5 mm and a thermal expansion coefficient in the range of 5 ppm/° C. to 8 ppm/° C., and that a minimum pitch of the through-hole conductors is in the range of 100 μm to 200 μm.

### CROSS-REFERENCE TO RELATED APPLICATIONS

The present application is based upon and claims the benefit of priority to Japanese Patent Application No. 2024-211520, filed Dec. 4, 2024, the entire contents of which are incorporated herein by reference.

### BACKGROUND OF THE INVENTION

### Field of the Invention The present invention relates to a wiring substrate.

### Description of Background Art

Japanese Patent Application Laid-Open Publication No. 2024-118643 describes a wiring substrate. The entire contents of this publication are incorporated herein by reference.

### SUMMARY OF THE INVENTION

According to one aspect of the present invention, a wiring substrate includes a core part including a glass plate, a first build-up part formed on a first surface of the glass plate and including conductor layers and insulating layers, and a second build-up part formed on a second surface of the glass plate on the opposite side with respect to the first surface and including conductor layers and insulating layers. Each of the first and second build-up parts is formed such that the conductor layers include four conductor layers and that the insulating layers include four insulating layers, the core part includes through-hole conductors formed in the glass plate such that the through-hole conductors connect the conductor layers in the first build-up part on the first surface of the glass plate and the conductor layers in the second build-up part on the second surface of the glass plate, and the core part is formed such that the glass plate has a thickness in the range of 0.7 mm to 1.5 mm and a thermal expansion coefficient in the range of 5 ppm/° C. to 8 ppm/° C., and that a minimum pitch of the through-hole conductors is in the range of 100 μm to 200 μm.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a plan view illustrating an example of formation of through-hole conductors in a wiring substrate according to an embodiment of the present invention;

FIG. 3A is a cross-sectional view illustrating an example of a manufacturing process of a wiring substrate according to an embodiment of the present invention;

FIG. 3B is a cross-sectional view illustrating an example of a manufacturing process of a wiring substrate according to an embodiment of the present invention;

FIG. 3C is a cross-sectional view illustrating an example of a manufacturing process of a wiring substrate according to an embodiment of the present invention;

FIG. 3D is a cross-sectional view illustrating an example of a manufacturing process of a wiring substrate according to an embodiment of the present invention;

FIG. 3E is a cross-sectional view illustrating an example of a manufacturing process of a wiring substrate according to an embodiment of the present invention;

FIG. 3F is a cross-sectional view illustrating an example of a manufacturing process of a wiring substrate according to an embodiment of the present invention;

FIG. 3G is a cross-sectional view illustrating an example of a manufacturing process of a wiring substrate according to an embodiment of the present invention; and

FIG. 3H is a cross-sectional view illustrating an example of a manufacturing process of a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Structure

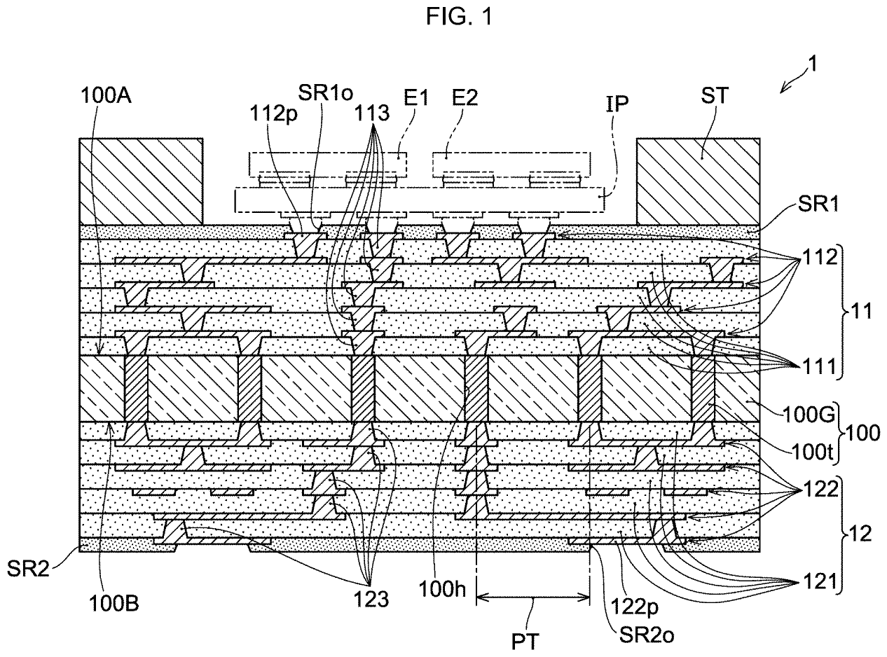

FIG. 1 illustrates a cross-sectional view of a wiring substrate 1, which is an example of a wiring substrate according to an embodiment of the present invention. The wiring substrate illustrated in the drawings referenced in the following description is merely an example of the wiring substrate of the embodiment. A laminated structure of the wiring substrate of the embodiment is not limited to the laminated structure of the wiring substrate illustrated in the drawings, and the number of conductor layers and the number of insulating layers included in the wiring substrate of the embodiment are not limited to the number of conductor layers and the number of insulating layers included in the wiring substrate illustrated in the drawings. The wiring substrate of the embodiment may include, in addition to the insulating layers and conductor layers included in the wiring substrate illustrated in the drawings, any number of insulating layers and conductor layers, and it is also possible that all of the insulating layers and conductor layers included in the wiring substrate illustrated in the drawings are not included. Further, in the drawings to be referenced in the following description, in order to facilitate understanding of the embodiment to be disclosed, a specific portion may be depicted in an enlarged manner. Therefore, it may be possible that structural elements of the wiring substrate of the embodiment are not depicted in precise proportions in terms of size or length relative to each other.

As illustrated in FIG. 1, the wiring substrate 1 includes a core part 100 that includes a glass plate (100G) and multiple through-hole conductors (100t) penetrating the glass plate (100G). The glass plate (100G) has a first surface (100A) and a second surface (100B) on an opposite side with respect to the first surface (100A). In the embodiment, the through-hole conductors (100t) are mainly formed of a conductive material that fills through holes (100h) penetrating the glass plate (100G). The wiring substrate 1 further includes build-up parts that are respectively formed on the two surfaces of the glass plate (100G). In the wiring substrate 1 of FIG. 1, a first build-up part 11 is formed on the first surface (100A) of the glass plate (100G), and a second build-up part 12 is formed on the second surface (100B) of the glass plate (100G).

In the wiring substrate of the embodiment, the build-up parts that are respectively formed on the two surfaces of the core part 100 are each composed of four or more conductor layers and four or more insulating layers. In the wiring substrate 1 of FIG. 1, the first build-up part 11 is composed of five insulating layers 111 and five conductor layers 112 laminated on the first surface (100A) of the glass plate (100G). The five insulating layers 111 and the five conductor layers 112 are alternately laminated. The second build-up part 12 is composed of five insulating layers 121 and five conductor layers 122 laminated on the second surface (100B) of the glass plate (100G). The five insulating layers 121 and the five conductor layers 122 are alternately laminated.

In the description of the wiring substrate of the embodiment, a side farther from the core part 100 is also referred to as “upper,” “upper side,” “outer side,” or “outer,” and a side closer to the core part 100 is also referred to as “lower,” “lower side,” “inner side,” or “inner.” Further, for the insulating layers and the conductor layers, a surface facing away from the core part 100 is also referred to as an “upper surface,” and a surface facing the core part 100 side is also referred to as a “lower surface.”

Each insulating layer 111 constituting the first build-up part 11 includes via conductors 113 that connect conductors (conductor layers 112, or a conductor layer 112 and the through-hole conductors (100t)) formed on both sides of the insulating layer 111 in a thickness direction. Each insulating layer 121 constituting the second build-up part 12 includes via conductors 123 that connect conductors (conductor layers 122, or a conductor layer 122 and the through-hole conductors (100t)) formed on both sides of the insulating layer 121 in the thickness direction.

In FIG. 1, adjacent through-hole conductors (100t) are formed at a pitch (PT). In the example of FIG. 1, the through-hole conductors (100t) are formed of a conductive material that entirely fills the through holes (100h), and the through holes (100h) are entirely filled with the through-hole conductors (100t). As will be described later, when the through-hole conductors (100t) are entirely formed of a conductive material such as copper, it may be possible that an overall thermal expansion coefficient of the through-hole conductors (100t) is close to that of the glass plate (100G). As a result, it may be possible that occurrence of defects such as cracks in the glass plate (100G) is suppressed.

The through-hole conductors (100t) are directly connected to the via conductors 113 and the via conductors 123. Therefore, the through-hole conductors (100t) connect the conductor layers 112 constituting the first build-up part 11 and the conductor layers 122 constituting the second build-up part 12 via the via conductors 113 and the via conductors 123.

A solder resist layer (SR1) is formed on the first build-up part 11. A solder resist layer (SR2) is formed on the second build-up part 12. Openings (SR1o) are formed in the solder resist layer (SR1), and conductor pads (112p) of the outermost conductor layer 112 in the first build-up part 11 are exposed from the openings (SR1o). Openings (SR2o) are formed in the solder resist layer (SR2), and conductor pads (122p) of the outermost conductor layer 122 in the second build-up part 12 are exposed from the openings (SR2o).

The conductor pads (112p) can be connection pads used for mounting an external electronic component or the like. As illustrated, the conductor pads (112p) can be electrically and mechanically connected by a bonding material such as solder to connection pads of an external member (IP), which can be, for example, a silicon interposer. In the example illustrated in FIG. 1, a component (E1) and a component (E2), which can be electronic components such as semiconductor integrated circuit devices or transistors (for example, logic chips or memory elements), are connected on the member (IP). That is, electronic components primarily mounted on an interposer may be mounted on the wiring substrate 1. On the other hand, the conductor pads (122p) may be used for connection to any substrate (such as an external motherboard), an electrical component, or a mechanical component (not illustrated).

In the example illustrated in FIG. 1, a reinforcing material (ST) is provided on the solder resist layer (SR1). The reinforcing material (ST) is provided so as to surround a region where the external member (IP) is mounted while avoiding a region where the conductor pads (112p) are provided, so as not to hinder mounting of components on the surface of the wiring substrate 1. It is thought that by providing the reinforcing material (ST), deformation such as warpage or bending of the wiring substrate 1 is suppressed. It is thought that by suppressing deformation of the wiring substrate 1, the components (E1, E2) can be stably mounted on the wiring substrate 1 and good connection reliability can be ensured.

The glass plate (100G) constituting the core part 100 is formed of glass selected from, for example, soda lime glass, aluminosilicate glass, and borosilicate glass. The glass plate (100G) may contain, as additives, magnesium, calcium, manganese, aluminum, lead, iron, chromium, potassium, sulfur, antimony, boron, or the like. In the wiring substrate of the embodiment, the glass plate (100G) has a thermal expansion coefficient of 5 ppm/° C. or more and 8 ppm/° C. or less. When the glass plate (100G) has a thermal expansion coefficient of 5 ppm/° C. or more and 8 ppm/° C. or less, it may be possible to reduce stress generated due to a difference in expansion or contraction amount between the first build-up part 11 and/or second build-up part 12 and the glass plate (100G) during a temperature change.

The insulating layers 111 constituting the first build-up part 11 and the insulating layers 121 constituting the second build-up part 12 are each formed, for example, using an insulating resin such as epoxy resin, bismaleimide triazine resin (BT resin), or phenol resin. The insulating layers (111, 121) may each contain a reinforcing material (base material) such as glass fiber and/or an inorganic filler such as silica or alumina. The insulating layers 111 and insulating layers 121 may each have a thermal expansion coefficient of, for example, 15 ppm/° C. or more and 25 ppm/° C. or less, by appropriately containing a reinforcing material and/or an inorganic filler, or without containing a reinforcing material and an inorganic filler. When the insulating layers (111, 121) have a thermal expansion coefficient of 15 ppm/° C. or more and 25 ppm/° C. or less, it may be possible to reduce stress generated due to a difference in expansion or contraction amount between the first build-up part 11 and/or second build-up part 12 and the glass plate (100G) during a temperature change.

The solder resist layers (SR1, SR2) are formed using, for example, a photosensitive epoxy resin or polyimide resin, or the like. The reinforcing material (ST) is formed of any material capable of suppressing deformation of the wiring substrate 1. For example, any metal material such as a copper alloy, an aluminum alloy, or an iron alloy may be used as a material for the reinforcing material (ST), and as an example, stainless steel having high rigidity is used.

The conductor layers (112, 122), the via conductors (113, 123), and the through-hole conductors (100t) can be formed using any metal such as copper or nickel. For example, the conductor layers (112, 122) can each be formed using a metal foil such as a copper foil and/or a metal film formed by plating or sputtering. In FIG. 1, the conductor layers (112, 122), the via conductors (113, 123), and the through-hole conductors (100t) are illustrated in a simplified manner as each having a single-layer structure for ease of viewing, but can each have a multilayer structure including two or more layers. The conductor layers (112, 122), the via conductors (113, 123), and the through-hole conductors (100t) can each have a two-layer structure including a metal film layer (for example, an electroless copper plating film) and a plating film layer (for example, an electrolytic copper plating film). The conductor layers (112, 122) included in the wiring substrate 1 are each patterned to have predetermined conductor patterns.

In FIG. 1, each of the through holes (100h) in which the through-hole conductors (100t) are formed is formed so as to have a substantially uniform inner diameter throughout its entire length in the thickness direction of the glass plate (100G). Each of the through holes (100h) (and therefore each of the through-hole conductor (100t)) may have a shape that is reduced in diameter toward its central portion in the thickness direction of the glass plate (100G) from the first surface (100A) side and the second surface (100B) side. For convenience, the term “reduced in diameter” is used. However, the shape of each of the through holes (100h) and through-hole conductor (100t)) in plan view is not necessarily limited to a circular shape. The term “diameter” refers to a linear distance between two most distant points on an outer edge of an object in plan view, and the term “reduced in diameter” means that the linear distance becomes smaller. Further, the term “in plan view” means viewing an object along the thickness direction of the wiring substrate 1 (that is, the thickness direction of the glass plate (100G)).

In the wiring substrate 1, the glass plate (100G) constituting the core part 100 has a thickness of 0.7 mm or more and 1.5 mm or less. Since a glass material, such as soda lime glass, which is a main material of the glass plate (100G), has superior rigidity compared to epoxy resin or the like, it is thought that even when the thickness of the glass plate (100G) is as small as 0.7 mm, remarkable warpage is unlikely to occur in the wiring substrate 1. Further, when the thickness of the glass plate (100G) is 1.5 mm or less, it is thought that through holes (100h) having a small diameter of, for example, about 100 μm can be easily formed.

Further, since the glass plate (100G) constituting the core part 100 has a thickness of 0.7 mm or more, even when the first build-up part 11 and the second build-up part 12 are each composed of four or more conductor layers and four or more insulating layers, warpage of the wiring substrate 1 may be suppressed. That is, although including many conductor layers and insulating layers in the first build-up part 11 and the second build-up part 12 may cause an imbalance in expansion or contraction between the two build-up parts due to a temperature change, warpage of the wiring substrate 1 may be unlikely to occur. The first build-up part 11 and the second build-up part 12 may each include each of the conductor layers and the insulating layers in a number of 20 or less, preferably 15 or less, and more preferably 10 or less. By constructing each build-up part with a certain number of layers or less, it may be possible to realize a wiring substrate having a thickness smaller than a desired thickness.

On the other hand, a glass material that excel in rigidity has lower toughness compared to an epoxy resin or the like, and therefore may be disadvantageous in terms of preventing crack occurrence due to thermal stress around the through holes (100h) or between the through holes (100h). In this regard, in the wiring substrate 1 of the embodiment, as described above, the glass plate (100G) has a thermal expansion coefficient of 5 ppm/° C. or more and 8 ppm/° C. or less, and further, by appropriately forming the through holes (100h), that is, by forming the through-hole conductors (100t) at appropriate positions according to a certain criterion, crack occurrence is suppressed. through-hole conductors

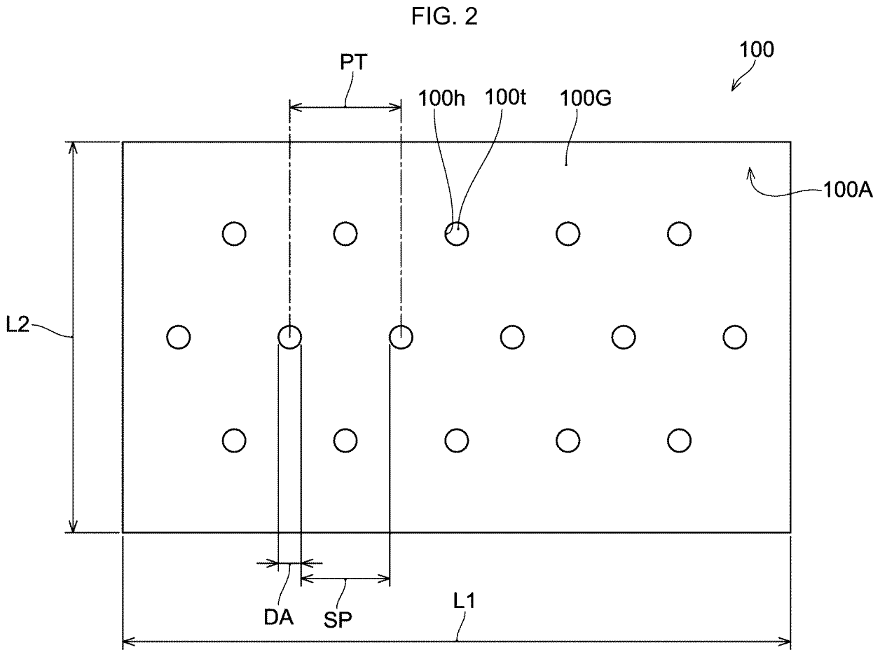

With reference to FIG. 2, the formation of the through-hole conductors in the glass plate of the wiring substrate of the embodiment is described. FIG. 2 illustrates an example of a plan view of the first surface (100A) of the glass plate (100G) in the wiring substrate 1 of the embodiment. As illustrated in FIG. 2, the through-holes (100h) are formed at predetermined positions in the glass plate (100G) in plan view, and the through-hole conductors (100t) are formed in the through holes (100h). The upper surfaces of the through-hole conductors (100t) are exposed on the first surface (100A) of the glass plate (100G).

In the example illustrated in FIG. 2, the glass plate (100G) has a rectangular planar shape. Among two pairs of opposing sides of the rectangular planar shape, each side of one pair has a length (L1), and each side of the other pair has a length (L2). In the glass plate (100G) of the wiring substrate of the embodiment, the length (L1) and the length (L2) may each be 50 mm or more. Since the glass plate (100G) has a thickness of 0.7 mm or more and a thermal expansion coefficient of 5 ppm/° C. or more and 8 ppm/° C. or less, it is thought that even when the glass plate (100G) is a relatively large glass plate with each side measuring 50 mm or more, defects such as cracks or fractures are unlikely to occur. Each side of the rectangular glass plate (100G) may have a length of 100 mm or less, preferably 85 mm or less, and more preferably 70 mm or less. When the glass plate (100G) has a length equal to or less than a certain value on each side, a wiring substrate with a size below a desired planar size may be realized.

Further, in the wiring substrate of the embodiment, the multiple through-hole conductors (100t) included in the core part 100 are formed at a formation pitch (PT) of 100 μm or more. That is, a minimum formation pitch (PT) of the multiple through-hole conductors (100t) is 100 μm or more. Therefore, two adjacent through-hole conductors (100t) are formed with at least a 100 μm distance between their centers. The formation pitch (PT) of the multiple through-hole conductors (100t) refers to a distance between two corresponding points (for example, between centers) of two adjacent through-hole conductors (100t). The “center” of each through-hole conductor (100t) refers to a design center position of the through hole (100h) used for forming the through-hole (100h).

In the wiring substrate of the embodiment, since the multiple through-hole conductors (100t) are formed with a formation pitch (PT) of at least 100 μm as described above, it is thought that sufficient resistance to strain that may occur due to a temperature change or the like is ensured between adjacent through-hole conductors (100t). That is, it is thought that a normal state can be maintained without damage during occurrence of stress such as thermal stress that is expected to occur between adjacent through-hole conductors (100t) or around each through-hole conductor (100t). Therefore, crack occurrence between the through-hole conductors (100t) or around each through-hole conductor (100t), that is, crack occurrence between the through holes (100h) or around each through hole (100h), can be suppressed. Therefore, according to the embodiment, it may be possible that reliability of the wiring substrate is improved.

The minimum formation pitch (PT) of the multiple through-hole conductors (100t) is preferably 150 μm or more. When the multiple through-hole conductors (100t) are formed with a formation pitch (PT) of at least 150 μm, it may be possible that crack occurrence between the through-hole conductors (100t) or around each through-hole conductor (100t) can be further suppressed.

On the other hand, the minimum formation pitch (PT) of the multiple through-hole conductors (100t) may be 200 μm or less. When the multiple through-hole conductors (100t) are formed with a formation pitch (PT) of 200 μm or less as necessary, it may be possible that the wiring substrate can be reduced in size.

A diameter (DA) of each through-hole conductor (100t) at the first surface (100A) and the second surface (100B) (see FIG. 1) of the glass plate (100G) refers to a maximum diameter of each through hole (100h) or each through-hole conductor (100t), and may be, for example, 50 μm or more and 150 μm or less. When the through-hole conductors (100t) have such a diameter (DA), it is thought that a spacing necessary for resistance to stress is ensured between adjacent through-hole conductors (100t). That is, a shortest distance between outer edges of adjacent through-hole conductors (100t) (spacing between the through-hole conductors) (SP) may be, for example, 50 μm or more and 150 μm or less.

### Method for Manufacturing Wiring Substrate

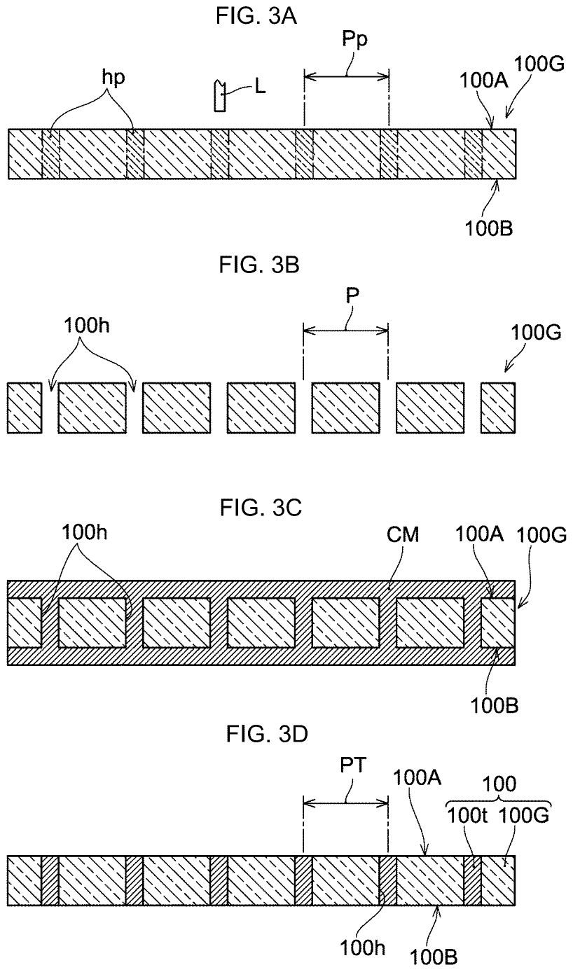

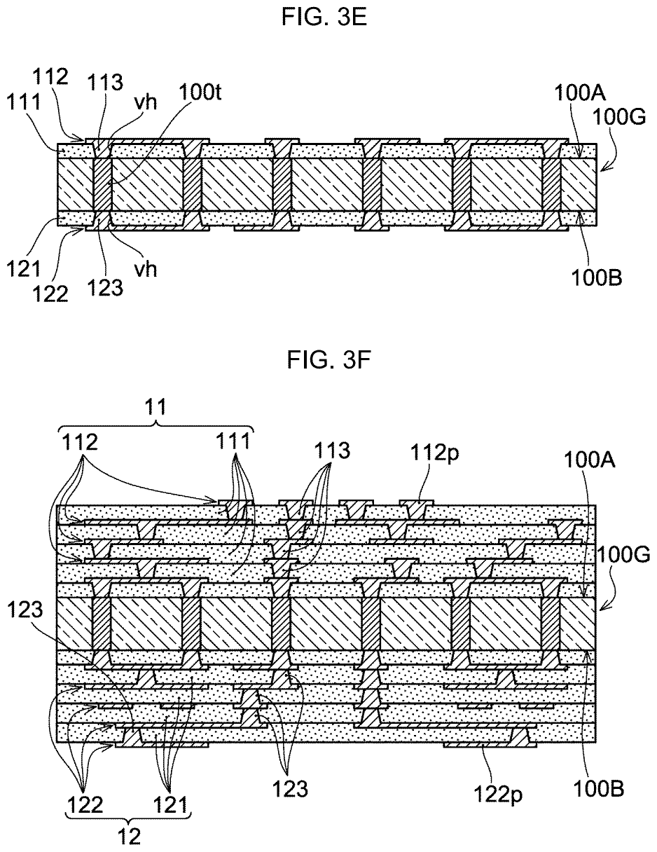

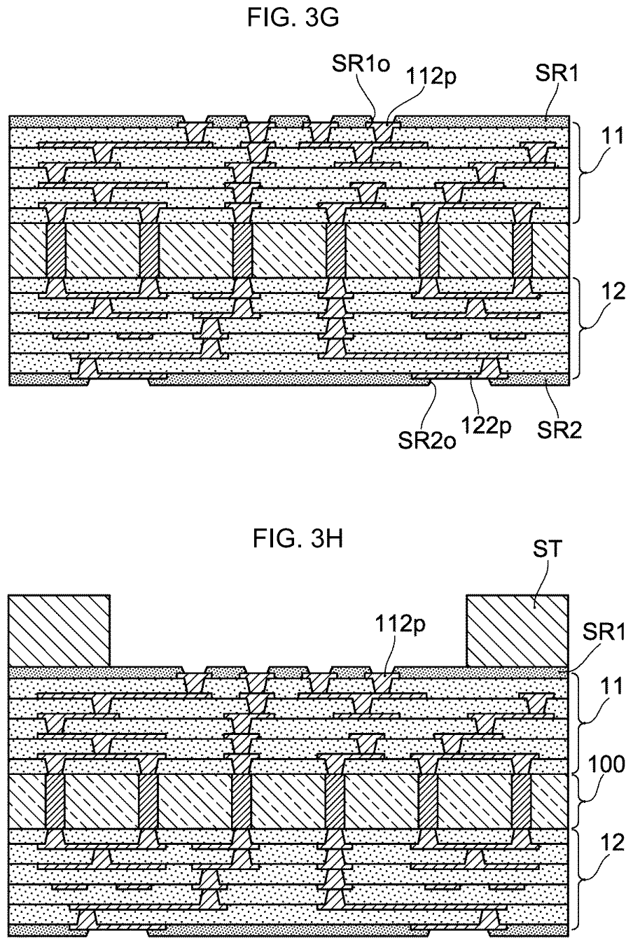

Next, with reference to FIGS. 3A-3H , an example of a method for manufacturing the wiring substrate of the present embodiment is described using a case where the wiring substrate 1 illustrated in FIG. 1 is manufactured as an example. Unless there is a description different from the description provided above regarding the materials of the structural elements of the wiring substrate 1, the structural elements can be formed using any of the materials described above with respect to the structural elements.

As illustrated in FIG. 3A, the glass plate (100G) having the first surface (100A) and the second surface (100B) is prepared. The prepared glass plate (100G) has a thickness of 0.7 mm or more and 1.5 mm or less and a thermal expansion coefficient of 5 ppm/° C. or more and 8 ppm/° C. or less. As the glass plate (100G) having a thermal expansion coefficient in this range, for example, a plate made of glass selected from soda lime glass, aluminosilicate glass, borosilicate glass, and the like may be prepared. Preferably, a glass plate (100G) having a rectangular or any planar shape and having a length of 50 mm or more in each of two orthogonal directions is prepared.

Then, laser light (L) is irradiated onto multiple positions in plan view where the through holes (100h) (see FIG. 3B) are to be formed in the glass plate (100G). As the laser light (L) passes through the glass plate (100G), the glass structure in a region through which the laser light (L) passes is altered so as to be more highly reactive to an etching solution used in a subsequent process than the glass structure in a region through which the laser light (L) does not pass. A modified portion (hp) formed of a portion where the glass structure has been altered is formed. The modified portion (hp) is formed along the thickness direction of the glass plate (100G) so as to extend from one to the other of the first surface (100A) and the second surface (100B) of the glass plate (100G). In the example illustrated in FIG. 3A, columnar modified portions (hp) each having a substantially constant diameter are formed. The modified portions (hp) are removed faster than surrounding unmodified portions in a subsequent etching process. That is, the through holes (100h) can be formed.

As the laser light (L), helium-neon lasers, argon ion lasers, excimer lasers, various YAG lasers, and the like can be used. From a point of view of facilitating the formation of the modified portions (hp) and avoiding excessive stress on the glass plate (100G), laser light (L) having a wavelength of about 350 nm or more and 3000 nm or less is preferably used. An output of the laser light (L) is appropriately adjusted so that the modified portions (hp) can be formed as intended. The laser light (L) may be irradiated continuously or in pulses.

In the manufacturing process of the wiring substrate of the embodiment, the laser light (L) is irradiated so that a formation pitch (Pp) between two adjacent modified portions (hp) among the multiple modified portions (hp) is 100 μm or more. That is, in forming the multiple modified portions (hp), the laser light (L) is irradiated with a spacing of at least 100 μm. By irradiating the laser light (L) in this way, crack occurrence around the modified portions (hp) due to heat generation accompanying the irradiation of the laser light (L) may be suppressed. Further, it is also thought that crack occurrence around the through holes (100h) (see FIG. 3B) due to heat or mechanical shock that may be applied in a subsequent process or after completion is suppressed.

On the other hand, the modified portions (hp) may be formed such that a minimum formation pitch (Pp) between the modified portions (hp) is 200 μm or less. That is, in forming the multiple modified portions (hp), the laser light (L) may be irradiated, as needed, with a spacing of only 200 μm or less. By forming the modified portions (hp) at a minimum pitch of 200 μm or less, it may be possible to form the through-hole conductors (100t) (see FIG. 3D) formed at a narrower pitch. That is, in the manufacturing process of the wiring substrate 1 of the embodiment, the multiple modified portions (hp) may be formed at a minimum formation pitch (Pp) of 100 μm or more and 200 μm or less.

The modified portions (hp) formed by irradiation of the laser light (L) are removed, for example, using an etching solution. Specifically, the modified portions (hp) are removed by immersing the glass plate (100G), in which the modified portions (hp) have been formed, in an etching solution containing, for example, an aqueous hydrofluoric acid solution. The concentration of the aqueous hydrofluoric acid solution is appropriately adjusted so that etching proceeds sufficiently. Further, from a point of view of promoting etching, the etching solution may contain hydrochloric acid and/or nitric acid, and ultrasonic waves may be propagated to an etching tank.

By removing the modified portions (hp) illustrated in FIG. 3A, as illustrated in FIG. 3B, the multiple cylindrical through holes (100h) penetrating the glass plate (100G) are formed. Through holes (100h) having any planar shape such as a circular shape are formed. The multiple through holes (100h) formed by removing the multiple modified portions (hp) formed at the formation pitch (Pp) illustrated in FIG. 3A are formed at a formation pitch (P) that is the same as the formation pitch (Pp). That is, a minimum formation pitch (P) of the multiple through holes (100h) is 100 μm or more. By forming the through holes (100h) at a formation pitch (P) of at least 100 μm, it is thought that crack occurrence around the through holes (100h) and/or between the through holes (100h) is suppressed. For example, the through holes (100h) having any diameter such as 100 μm may be formed. However, a nonzero spacing is provided between the through holes (100h).

As described above, since the multiple modified portions (hp) are formed such that the minimum formation pitch (Pp) between the modified portions (hp) is 200 μm or less when necessary, the minimum formation pitch (P) of the multiple through holes (100h) may also be 200 μm or less. The through-hole conductors (100t) (see FIG. 3D) formed at a narrower pitch are formed, and thus, it may be possible to manufacture a wiring substrate smaller.

After the through holes (100h) are formed, preferably, a metal oxide film (not illustrated) such as tin oxide or zinc oxide is formed, for example, using a chemical vapor deposition method or the like, on the entire surface of the glass plate (100G) and on the entire inner wall surfaces exposed in the through holes (100h). By forming the metal oxide film, adhesion between glass and metal can be improved.

As illustrated in FIG. 3C, the through holes (100h) are filled with a conductive material (CM). For example, by electroless plating or sputtering, a seed metal film made of an appropriate metal such as copper or nickel is formed on the entire surface of the glass plate (100G) and on the entire inner wall surfaces exposed in the through holes (100h). Further, by electrolytic plating using the formed seed metal film as a power feeding layer, an electrolytic plating film made of an appropriate metal such as copper is formed. The conductive material (CM) composed of the seed metal film and the electrolytic plating film is formed. The through holes (100h) are substantially completely filled with the conductive material (CM), and the first surface (100A) and the second surface (100B) of the glass plate (100G) are covered by the conductive material (CM).

The conductive material (CM) covering the surfaces of the glass plate (100G) is removed, for example, by chemical mechanical polishing (CMP). As illustrated in FIG. 3D, the first surface (100A) and the second surface (100B) of the glass plate (100G) are exposed. Further, the conductive material (CM) of FIG. 3C in the through holes (100h) remains as the through-hole conductors (100t). The through-hole conductors (100t) formed at a minimum formation pitch (PT) of 100 μm or more and preferably 200 μm or less are obtained. The formation of the core part 100 composed of the glass plate (100G) including the through-hole conductors (100t) is thus completed. One end surface of each through-hole conductor (100t) is substantially flush with the first surface (100A) of the glass plate (100G) and exposed at the first surface (100A), and the other end surface of the through-hole conductor (100t) is substantially flush with the second surface (100B) and exposed at the second surface (100B).

As illustrated in FIG. 3E, an insulating layer 111 is formed on the first surface (100A) of the glass plate (100G), and an insulating layer 121 is formed on the second surface (100B) of the glass plate (100G). The insulating layer 111 and the insulating layer 121 are formed, for example, by laminating and thermocompression bonding resin films formed of epoxy resin or the like on both sides of the core part 100. Preferably, resin films that can have a thermal expansion coefficient of 15 ppm/° C. or more and 25 ppm/° C. or less after thermocompression bonding are used. In the insulating layer 111 and the insulating layer 121, through holes (vh) are formed at positions where via conductors 113 or via conductors 123 are to be formed, for example, by irradiation with CO2 laser light. Then, for example, using a semi-additive method, a conductor layer 112 is formed on the insulating layer 111, and a conductor layer 122 is formed on the insulating layer 121. Via conductors 113 are formed in the through holes (vh) of the insulating layer 111, and via conductors 123 are formed in the through holes (vh) of the insulating layer 121. The via conductors 113 are formed in contact with the end surfaces of the through-hole conductors (100t) exposed at the first surface (100A), and the via conductors 123 are formed in contact with the end surfaces of the through-hole conductors (100t) exposed at the second surface (100B).

As illustrated in FIG. 3F, on the first surface (100A) side of the glass plate (100G), four additional sets of insulating layers 111 and conductor layers 112 are formed in the same manner as the insulating layer 111 and conductor layer 112 formed in the process illustrated in FIG. 3E. Via conductors 113 are formed in each of the thus formed insulating layers 111. The conductor pads (112p) are provided in the outermost conductor layer 112. As a result, the first build-up part 11 is formed. Similarly, on the second surface (100B) side of the glass plate (100G), four additional sets of insulating layers 121 and conductor layers 122 are formed. Via conductors 123 are formed in each of the thus formed insulating layers 121. The conductor pads (122p) are provided in the outermost conductor layer 122. As a result, the second build-up part 12 is formed.

As illustrated in FIG. 3G, the solder resist layer (SR1) is formed on the first build-up part 11, and the solder resist layer (SR2) is formed on the second build-up part 12. The solder resist layer (SR1) and the solder resist layer (SR2) are each formed, for example, by forming a resin film of a photosensitive epoxy resin or polyimide resin or the like by spraying or lamination. The openings (SR1o, SR2o) are formed in the solder resist layers (SR1, SR2), for example, by photolithography. On surfaces of the conductor pads (112p, 122p) exposed in the openings (SR1o, SR2o), a surface protection film (not illustrated) made of Au, Ni/Au, Ni/Pd/Au, solder, or heat-resistant preflux or the like may be formed, for example, by electroless plating, solder leveling, spray coating, or the like.

As illustrated in FIG. 3H, the reinforcing material (ST) is positioned on the solder resist layer (SR1). The reinforcing material (ST) is positioned in a region where the conductor pads (112p) are not formed, preferably so as to surround a region where the conductor pads (112p) are formed. The reinforcing material (ST) is, for example, formed separately from the core part 100 and the first and second build-up parts (11, 12). The reinforcing material (ST) is formed, for example, by machining or molding a metal such as stainless steel into a desired shape. The separately formed reinforcing material (ST) is positioned, for example, on the surface of the solder resist layer (SR1) using a thermosetting resin. Through the above processes, the wiring substrate 1 in the example of FIG. 1 is completed.

The wiring substrate of the embodiment is not limited to those having the structures illustrated in the drawings and those having the structures, shapes, and materials exemplified herein. As described above, the wiring substrate of the embodiment can have any laminated structure. The wiring substrate of the embodiment can have any number of conductor layers and insulating layers. Each conductor layer may include any conductor patterns. The core part may have conductor layers on the two surfaces of the glass plate. The through holes penetrating the glass plate do not necessarily have to be entirely filled with through-hole conductors, and resin may be filled inside tubular through-hole conductors. A strength-enhancing material such as the reinforcing material (ST) is not necessarily provided, and an electronic component may be directly mounted on the wiring substrate of the embodiment without using an interposer.

Japanese Patent Application Laid-Open Publication No. 2024-118643 describes a wiring substrate. The wiring substrate has a core substrate that includes a substrate made of glass and through-hole conductors penetrating the substrate. On both sides of the core substrate, resin insulating layers and conductor layers are alternately laminated.

In the wiring substrate disclosed in Japanese Patent Application Laid-Open Publication No. 2024-118643, it is thought that cracks may occur around the through-hole conductors in the glass substrate.

A wiring substrate according to an embodiment of the present invention includes: a core part that includes a glass plate having a first surface and a second surface on an opposite side with respect to the first surface; and build-up parts that are respectively formed on the two surfaces of the glass plate and are each composed of laminated conductor layers and insulating layers. The build-up parts are each composed of four or more conductor layers and four or more insulating layers. The core part includes multiple through-hole conductors that connect the conductor layers in the build-up part formed on the first surface side and the conductor layers in the build-up part formed on the second surface side. The glass plate has a thickness of 0.7 mm or more and 1.5 mm or less and a thermal expansion coefficient of 5 ppm/° C. or more and 8 ppm/° C. or less. A minimum formation pitch of the multiple through-hole conductors is 100 μm or more and 200 μm or less.

According to an embodiment of the present invention, it is thought that crack occurrence in the glass plate constituting the core part is suppressed, and thus, quality of the wiring substrate is improved.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core part comprising a glass plate;
a first build-up part formed on a first surface of the glass plate and comprising a plurality of conductor layers and a plurality of insulating layers; and
a second build-up part formed on a second surface of the glass plate on an opposite side with respect to the first surface and comprising a plurality of conductor layers and a plurality of insulating layers,
wherein each of the first and second build-up parts is formed such that the plurality of conductor layers includes four conductor layers and that the plurality of insulating layers includes four insulating layers, the core part includes a plurality of through-hole conductors formed in the glass plate such that the plurality of through-hole conductors is configured to connect the conductor layers in the first build-up part on the first surface of the glass plate and the conductor layers in the second build-up part on the second surface of the glass plate, and the core part is formed such that the glass plate has a thickness in a range of 0.7 mm to 1.5 mm and a thermal expansion coefficient in a range of 5 ppm/° C. to 8 ppm/° C., and that a minimum pitch of the through-hole conductors is in a range of 100 μm to 200 μm.

2. The wiring substrate according to claim 1, wherein the core part is formed such that the glass plate has a rectangular planar shape with each side measuring 50 mm or more.

3. The wiring substrate according to claim 1, wherein each of the first and second build-up parts is formed such that the insulating layers have a thermal expansion coefficient in a range of 15 ppm/° C. to 25 ppm/° C.

4. The wiring substrate according to claim 1, wherein the core part is formed such that a minimum pitch of the through-hole conductors is 150 μm or more.

5. The wiring substrate according to claim 1, wherein the core part is formed such that the through-hole conductors comprise conductive material entirely filling through holes penetrating through the glass plate, respectively.

6. The wiring substrate according to claim 1, wherein the core part is formed such that the plurality of through-hole conductors has a shortest distance in a range of 50 μm to 150 μm between outer edges of the through-hole conductors.

7. The wiring substrate according to claim 2, wherein each of the first and second build-up parts is formed such that the insulating layers have a thermal expansion coefficient in a range of 15 ppm/° C. to 25 ppm/° C.

8. The wiring substrate according to claim 2, wherein the core part is formed such that a minimum pitch of the through-hole conductors is 150 μm or more.

9. The wiring substrate according to claim 2, wherein the core part is formed such that the through-hole conductors comprise conductive material entirely filling through holes penetrating through the glass plate, respectively.

10. The wiring substrate according to claim 2, wherein the core part is formed such that the plurality of through-hole conductors has a shortest distance in a range of 50 μm to 150 μm between outer edges of the through-hole conductors.

11. The wiring substrate according to claim 3, wherein the core part is formed such that a minimum pitch of the through-hole conductors is 150 μm or more.

12. The wiring substrate according to claim 3, wherein the core part is formed such that the through-hole conductors comprise conductive material entirely filling through holes penetrating through the glass plate, respectively.

13. The wiring substrate according to claim 3, wherein the core part is formed such that the plurality of through-hole conductors has a shortest distance in a range of 50 μm to 150 μm between outer edges of the through-hole conductors.

14. The wiring substrate according to claim 4, wherein the core part is formed such that the through-hole conductors comprise conductive material entirely filling through holes penetrating through the glass plate, respectively.

15. The wiring substrate according to claim 4, wherein the core part is formed such that the plurality of through-hole conductors has a shortest distance in a range of 50 μm to 150 μm between outer edges of the through-hole conductors.

16. The wiring substrate according to claim 5, wherein the core part is formed such that the plurality of through-hole conductors has a shortest distance in a range of 50 μm to 150 μm between outer edges of the through-hole conductors.

17. The wiring substrate according to claim 7, wherein the core part is formed such that a minimum pitch of the through-hole conductors is 150 μm or more.

18. The wiring substrate according to claim 7, wherein the core part is formed such that the through-hole conductors comprise conductive material entirely filling through holes penetrating through the glass plate, respectively.

19. The wiring substrate according to claim 7, wherein the core part is formed such that the plurality of through-hole conductors has a shortest distance in a range of 50 μm to 150 μm between outer edges of the through-hole conductors.

20. The wiring substrate according to claim 17, wherein the core part is formed such that the through-hole conductors comprise conductive material entirely filling through holes penetrating through the glass plate, respectively.
